(19) United States
(12) Patent Application Publication
(10) Pub. No.: US 2025/0358042 A1
(43) Pub. Date: Nov. 20, 2025

(54) MULTI-WIRE PERMUTED FORWARD ERROR CORRECTION

(71) Applicant: Kandou Labs SA, Saint-Sulpice (CH)

(72) Inventors: Amin Shokrollahi, Saint-Sulpice (CH); Ali Hormati, Saint-Sulpice (CH)

(73) Assignee: Kandou Labs SA, Saint-Sulpice (CH)

(21) Appl. No.: 19/207,266

(22) Filed: May 13, 2025

Related U.S. Application Data
(63) Continuation of application No. 18/416,434, filed on Jan. 18, 2024, now Pat. No. 12,301,352.
Application No. 18/416,434 is a continuation of application No. 17/845,638, filed on Jun. 21, 2022, now Pat. No. 11,894,926.
Application No. 17/845,638 is a continuation of application No. 16/909,525, filed on Jun. 23, 2020, now Pat. No. 11,368,247.

(51) Int. Cl. H04L 1/00; H03M 13/00; H03M 13/05; H03M 13/15; H03M 13/27; H03M 13/37; H04J 13/00; H04L 25/02; H04L 25/08

(52) U.S. Cl. CPC H04L 1/0041; H03M 13/05; H03M 13/1515; H03M 13/27; H03M 13/3761; H03M 13/6561; H04J 13/004; H04L 1/0071; H04L 25/0272; H04L 25/085

(57) ABSTRACT

Methods and systems are described for obtaining a plurality of information bits, and responsively partitioning the obtained plurality of information bits into a plurality of subsets of information bits, generating a plurality of streams of forward error correction (FEC)-encoded bits using a plurality of FEC encoders receiving respective subsets of the plurality of subsets of information bits, providing the plurality of streams of FEC-encoded bits to a plurality of sub-channel encoders, each sub-channel encoder receiving a respective stream of FEC-encoded bits from a different FEC encoder of the plurality of FEC encoders for generating a set of codewords of a vector signaling code, and wherein sequential streams of FEC-encoded bits from a given FEC encoder are provided to different sub-channel encoders for each successively generated set of codewords, and transmitting the successively generated sets of codewords of the vector signaling code over a multi-wire bus.

### CROSS-REFERENCE TO RELATED APPLICATIONS

This application is a continuation of U.S. application Ser. No. 18/416,434, filed Jan. 18, 2024, entitled “Multi-Wire Permuted Forward Error Correction”, which is a continuation of U.S. application Ser. No. 17/845,638, filed Jun. 21, 2022, now U.S. Pat. No. 11,894,926, granted Feb. 6, 2024, entitled “Multi-Wire Permuted Forward Error Correction”, which is a continuation of U.S. application Ser. No. 16/909,525, filed Jun. 23, 2020, now U.S. Pat. No. 11,368,247, granted Jun. 21, 2022, entitled “Multi-Wire Permuted Forward Error Correction”, which is a continuation of U.S. application Ser. No. 16/031,877, filed Jul. 10, 2018, now U.S. Pat. No. 10,693,587, granted Jun. 23, 2020, naming Amin Shokrollahi, entitled “Multi-Wire Permuted Forward Error Correction”, which claims the benefit of U.S. Provisional Application No. 62/530,809, filed Jul. 10, 2017, naming Amin Shokrollahi and Ali Hormati, entitled “Multi-Wire Permuted Forward Error Correction”, all of which are hereby incorporated herein by reference in their entirety for all purposes.

### REFERENCES

The following prior applications are herein incorporated by reference in their entirety for all purposes:
U.S. Pat. No. 9,288,089 of application Ser. No. 12/784,414, filed May 20, 2010, naming Harm Cronie and Amin Shokrollahi, entitled “Orthogonal Differential Vector Signaling” (hereinafter “Cronie I”).
U.S. Pat. No. 9,667,379 of application Ser. No. 13/154,009, filed Jun. 5, 2011, naming Harm Cronie and Amin Shokrollahi, entitled “Error Control Coding for Orthogonal Differential Vector Signaling” (hereinafter “Cronie II”).
U.S. Pat. No. 9,596,109 of application Ser. No. 14/253,584, filed Apr. 15, 2014, naming John Fox, Brian Holden, Ali Hormati, Peter Hunt, John D Keay, Amin Shokrollahi, Anant Singh, Andrew Kevin John Stewart, Giuseppe Surace, and Roger Ulrich, entitled “Methods and Systems for High Bandwidth Communications Interface” (hereinafter called “Fox I”)
U.S. Pat. No. 8,296,632 of application Ser. No. 12/479,605, filed Jun. 5, 2009, naming Amin Shokrollahi, entitled “Encoding and decoding of generalized Reed-Solomon codes using parallel processing techniques” (hereinafter “Shokrollahi I”).
U.S. Pat. No. 9,100,232 of application Ser. No. 14/612,241, filed Aug. 4, 2015, naming Amin Shokrollahi, Ali Hormati, and Roger Ulrich, entitled “Method and Apparatus for Low Power Chip-to-Chip Communications with Constrained ISI Ratio”, hereinafter identified as [Shokrollahi II].
U.S. Provisional Patent Application No. 62/485,677, filed Apr. 14, 2017, naming Amin Shokrollahi and Dario Carnelli, entitled “Pipelined Forward Error Correction for Vector Signaling Code Channel”, hereinafter identified as [Shokrollahi III].

### FIELD OF THE INVENTION

The present embodiments relate to communications systems circuits generally, and more particularly to reduction of communication errors over a high-speed multi-wire interface used for chip-to-chip communication.

### BACKGROUND

In modern digital systems, digital information has to be processed in a reliable and efficient way. In this context, digital information is to be understood as information available in discrete, i.e., discontinuous values. Bits, collection of bits, but also numbers from a finite set can be used to represent digital information.

In most chip-to-chip, or device-to-device communication systems, communication takes place over a plurality of wires to increase the aggregate bandwidth. A single or pair of these wires may be referred to as a channel or link and multiple channels create a communication bus between the electronic components. At the physical circuitry level, in chip-to-chip communication systems, buses are typically made of electrical conductors in the package between chips and motherboards, on printed circuit boards (“PCBs”) boards or in cables and connectors between PCBs. In high frequency applications, microstrip or stripline PCB traces may be used.

Common methods for transmitting signals over bus wires include single-ended and differential signaling methods. In applications requiring high speed communications, those methods can be further optimized in terms of power consumption and pin-efficiency, especially in high-speed communications. More recently, vector signaling methods have been proposed to further optimize the trade-offs between power consumption, pin efficiency and noise robustness of chip-to-chip communication systems. In those vector signaling systems, digital information at the transmitter is transformed into a different representation space in the form of a vector codeword that is chosen in order to optimize the power consumption, pin-efficiency and speed trade-offs based on the transmission channel properties and communication system design constraints. Herein, this process is referred to as “encoding”. The encoded codeword is communicated as a group of signals from the transmitter to one or more receivers. At a receiver, the received signals corresponding to the codeword are transformed back into the original digital information representation space. Herein, this process is referred to as “decoding”.

### BRIEF DESCRIPTION

In conventional bit-serial communications systems, data words provided by a transmitting or source process are serialized into a sequential stream of bits, in one exemplary embodiment using a digital shift register. At the receiver, sequentially detected bits are deserialized using comparable means, so that a receiving or destination process may be presented with complete data words equivalent to those provided at the transmitter. Vector signaling code communication systems perform comparable operations, although in these embodiments the serialization process generally breaks words into symbol groups (e.g. into five bit elements for a CNRZ-5 system) and the equivalent deserialization process assembles received groups (of five bits, continuing the same example) into words again.

Forward Error Correction (FEC) methods have been developed which introduce redundancy into such transmitted data streams as part of a check code that both detects and facilitates correction of errors. The order in which data and redundancy information are structured into a transmitted data stream can significantly impact overall communication latency, especially if multiple essentially parallel communications channels are involved. Solutions are described utilizing interleaving to optimize both burst error control and latency.

Embodiments are described for permuting the transmission order of FEC encoded packets from multiple encoding streams such that sequential packets from each stream are not transmitted sequentially on the same sub-channel nor simultaneously on another sub-channel of a multi sub-channel vector signaling code sent over a multi-wire bus.

Methods and systems are described for obtaining a plurality of information bits, and responsively partitioning the obtained plurality of information bits into a plurality of subsets of information bits, generating a plurality of streams of forward error correction (FEC)-encoded bits using a plurality of FEC encoders receiving respective subsets of the plurality of subsets of information bits, providing the plurality of streams of FEC-encoded bits to a plurality of sub-channel encoders, each sub-channel encoder receiving a respective stream of FEC-encoded bits from a different FEC encoder of the plurality of FEC encoders for generating a set of codewords of a vector signaling code, and wherein sequential streams of FEC-encoded bits from a given FEC encoder are provided to different sub-channel encoders for each successively generated set of codewords, and transmitting the successively generated sets of codewords of the vector signaling code over a multi-wire bus.

### BRIEF DESCRIPTION OF FIGURES

FIG. 1 is a block diagram of a system that may serve as the physical transport for the described embodiments, with transmitter 110 communicating over a multiwire 125 communications channel 120 to receiver 130.

FIG. 2 is a more detailed block diagram of Transmitter 110 of FIG. 1.

FIG. 3 is a more detailed block diagram of Receiver 130 of FIG. 1.

FIG. 4 is a block diagram of an embodiment of an error corrected system, where lower-level transport and PHY 430 may be the systems of FIGS. 1-3.

FIG. 5A illustrates operation of Digital Integrator 420 of FIG. 4, and FIG. 5B illustrates operation of the Digital Differentiator function 440 of FIG. 4.

FIG. 6 is a block diagram showing the Distribution of incoming data bytes to multiple FEC Encoders, with the resulting output streams being acted upon by a permuter function prior to transport.

FIG. 7 illustrates three FEC protected data streams passed directly to three transport sub-channels, without permutation.

FIG. 8 illustrates three FEC protected data streams mapped in reoccurring order to three transport sub-channels.

FIG. 9 illustrates three FEC protected data streams mapped in a cyclically varying order to three transport sub-channels.

FIG. 10 shows one embodiment of a permuter subsystem.

FIG. 11 shows another embodiment of a permuter subsystem.

FIG. 12 is a flowchart of a method, in accordance with some embodiments.

### DETAILED DESCRIPTION

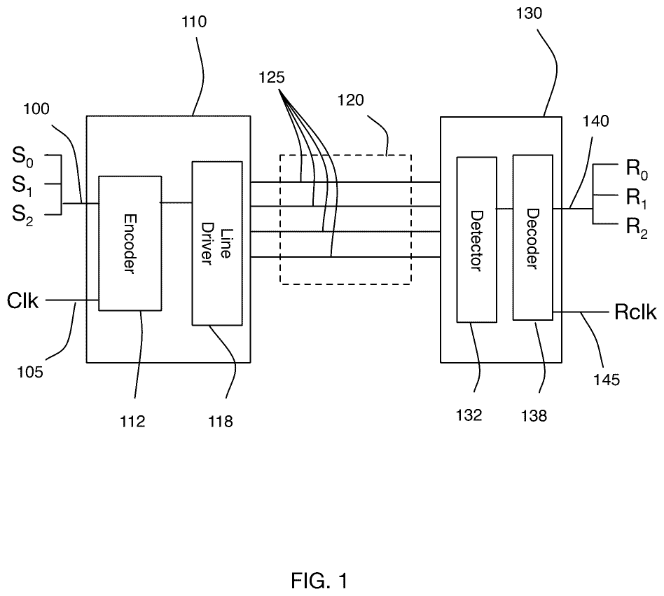

As described in [Cronie I], [Cronie II], and [Shokrollahi II], vector signaling codes may be used to produce extremely high bandwidth data communications links, such as between two integrated circuit devices in a system. As illustrated by the embodiment of FIG. 1, a data communications channel 120 comprised of multiple wires 125 carries symbols of the vector signaling code, acting together to communicate codewords of the vector signaling code. Depending on the particular vector signaling code used, the number of wires making up a communications link or multi-wire bus may range from two to eight or more, and may also communicate one or more clock signals on separate wires or as sub-channel components of the vector signaling code. In the example of FIG. 1, communication link 120 is illustrated as being composed of eight wires 125, collectively communicating five data values 100 and one clock 105 between transmitter 110 and receiver 130. Further descriptions of such communications links are provided in [Shokrollahi II].

Individual symbols, e.g. transmissions on any single wire, may utilize multiple signal levels, often three or more. Operation at channel rates exceeding 10 Gbps may further complicate receive behavior by requiring deeply pipelined or parallelized signal processing. Embodiments described herein can also be applied to prior art permutation sorting methods not covered by the vector processing methods of [Shokrollahi II]. More generally, embodiments may apply to any communication or storage methods utilizing coordination of multiple channels or elements of the channel to produce a coherent aggregate result.

Because of its characteristic of transmitting multiple symbols essentially in parallel, vector signaling codes are generally considered as communicating data in symbol groups, for example in five-bit increments for the CNRZ-5 code of [Shokrollahi II], or in three-bit increments for the H4 code of [Shokrollahi I], also described in [Fox I] as the Enhanced Non-Return to Zero or ENRZ code. High-bandwidth systems may utilize multiple vector signaling code channels, distributing data across the multiple channels for transmission, and gathering received data from the multiple channels to be transparently combined again at the receiver. Thus, this document may subsequently describe transport as occurring in increments of K*n bits, where n is that code's symbol group or payload size. That reference additionally notes, however, that the encoded sub-channels transporting individual bits are mathematically distinct, and in certain embodiments may be treated as independent transport channels.

### Serialization and Deserialization

In conventional bit-serial communications systems, data words provided by a transmitting or source process are serialized into a sequential stream of bits, in one exemplary embodiment using a digital shift register. At the receiver, sequentially detected bits are deserialized using comparable means, so that a receiving or destination process may be presented with complete data words equivalent to those provided at the transmitter. Vector signaling code communication systems perform comparable operations, although in these embodiments the serialization process generally breaks words into symbol groups (e.g. into five bit elements for a CNRZ-5 system) and the equivalent deserialization process assembles received groups (of five bits, continuing the same example) into words again.

As is readily apparent, serialization and deserialization introduce latency into the communication channel, with the amount of latency dependent on the number of transmitted elements into which a given data word is serialized, as the entire word is not available until its last-transmitted element has been received and the received word fully reassembled.

In some high-speed communications systems, serialization and deserialization may additionally incorporate multiple processing phases operating essentially in parallel, to provide additional processing time within each phase and/or to permit processing operation using a lower clock rate to reduce power consumption. In one representative embodiment, data words presented by the transmission or source process are broken into symbol groups, with consecutive symbol groups being assigned to sequentially chosen processing phases which perform the necessary encoding, formatting, etc. As each processing phase completes its operations, the processed results are transferred to an output driver for transmission over the communications medium. Thus, in the case where four processing phases are used, each phase will have approximately four transmit unit intervals of time to perform the necessary operations. Similar multiphase processing may occur at the receiver; consecutively received symbol groups being detected by sequentially assigned processing phases and reassembled into output words.

Embodiments incorporating multiple processing phases are used herein as descriptive examples, so as to provide the broadest and most complete illustration of features and behaviors. Other embodiments may utilize fewer or more processing phases, including a single instance, and may incorporate greater or lesser amount of transmit and/or receive processing into the essentially parallel processing phases, with no limitation implied by these examples.

### Link Error Correction

Communications system designs emphasize error-free transport of data, despite the inevitable presence of noise and other signal disruptions. Error probabilities over the communications path are expressed as a Bit Error Rate (BER), representing the ratio of bit errors received to overall bits transmitted.

Solutions to detect bit errors, including cyclic check codes, parity, and redundant transmission, are known in the art. Similarly, solutions are known for correction of errors, most notably the closed-loop retransmission methods of the TCP/IP protocol suite, in which a receiver detects an error, uses a return channel to request a retransmission by the transmitter, and then transparently inserts the corrected data into its output stream.

### Forward Error Correction

Where use of a return channel is impossible or the round-trip latency of waiting for a retransmission is unacceptable, Forward Error Correction (FEC) methods have been developed which introduce redundancy into the transmitted data stream as part of a check code that both detects and facilitates correction of errors. The more redundancy introduced into the transmitted data stream (e.g. by use of a longer FEC sequence) the greater the ability of the FEC to correct bit errors, but also the greater the protocol overhead, presenting itself as a lower effective data transmission rate.

In cases where the native communications link has relatively low uncorrected BER (e.g., 1×10⁻⁹ to 1×10⁻¹⁰) and the target BER is of the order of 1×10⁻¹⁵ to 1×10⁻²⁰, other solutions can be found with much lower latency. This is the case, as one example, for the low latency FEC of [Shokrollahi III], targeted for in-package die-to-die links that use vector signaling code such as the Glasswing or CNRZ-5 code of [Shokrollahi II].

One embodiment of a link-optimized Forward Error Correction uses sequential data word transmission by the transport level vector signaling code to minimize perceived error correction latency. In such an embodiment, a vector signaling code transport communicates groups of n bits over m wires. Transmission of N consecutive groups thus transfers N*n bits, consisting of K*n data bits and R*n CRC bits for error correction. At the transmitter, a data source provides the K*n data bits, typically as multiple transfers over a wide parallel interface, with a similar interface delivering the received K*n data bits to a data sink at the receiver.

At the transmitter, this embodiment performs the following operations:

The 5 bits to be transmitted at each Unit Interval (UI) are treated as elements of the field GF(32). For example, If n0, n1, n2, n3, n4 denote the 5 bits, wherein n0 is the lowest significant bit of n and n4 is the highest significant bit, then n corresponds to the element

$$n 0 + n 1 * x + n 2 * x ⊕ 2 + n 3 * x ⊕ 3 + n 4 * x ⊕ 4 mod f ( x ) \qquad ( Eqn . 2 )$$

where ⊕ denotes the bit-wise XOR operation and f(x) is the polynomial x⊕5+x⊕3+1

We use a matrix of elements of GF(32) with 2 rows and 30 columns. The elements in column j of this matrix are 1 and the element aⱼ of GF(32) corresponding to the binary expansion of j, that is, the vector j0, j1, j2, j3, j4 where j0+2*j1+4*j2+8*j3+16*j4=j.

If the incoming 30 5-bit data words (the bits of which will be communicated essentially simultaneously on the 5 CNRZ-5 sub-channels) are denoted by m0, m1, . . . , m29, then the two CRC 5-bit words, denoted r0 and r1, are obtained as r0=m0⊕m1⊕ . . . ⊕m29 and r1=a0·m0⊕a1·m1⊕ . . . ⊕a29·m29 wherein a·b denotes the multiplication of a and b in the field GF(32) and ⊕ denotes the bit-wise XOR operation.

The message data m0, m1, . . . m29 corresponds to 5-bit words at time instance 0, 1, . . . , 29; therefore, the computation of CRC words r0, r1 can be done incrementally, as the data becomes available. The computation is equivalent to

$$Set r 0 = r 1 = 0$$

$$For j from 0 to 29 do$$

$$r 0 [ i ] = r 0 [ i ] ⊕ mj [ i ]$$

$$r 1 = r 1 ⊕ aj \cdot mj$$

### Example Embodiment

For purposes of explanation and without implying limitation, the reference system for the following descriptions is assumed to have the following characteristics:
Underlying transport providing three sub-channels using ENRZ coding at a 25 Gigasymbol/second rate, equivalent to a 40 picosecond unit interval.
Uncorrected BER in the range of 10E-8 to 10E-9, comprised of both random bit and short burst errors.
Corrected FER or BER less than 10E-19
FEC latency of 80 ns or less.

FIG. 1 is a block diagram of a system that may serve as the physical transport for such a system, with transmitter 110 communicating over a multiwire 125 communications channel 120 to receiver 130.

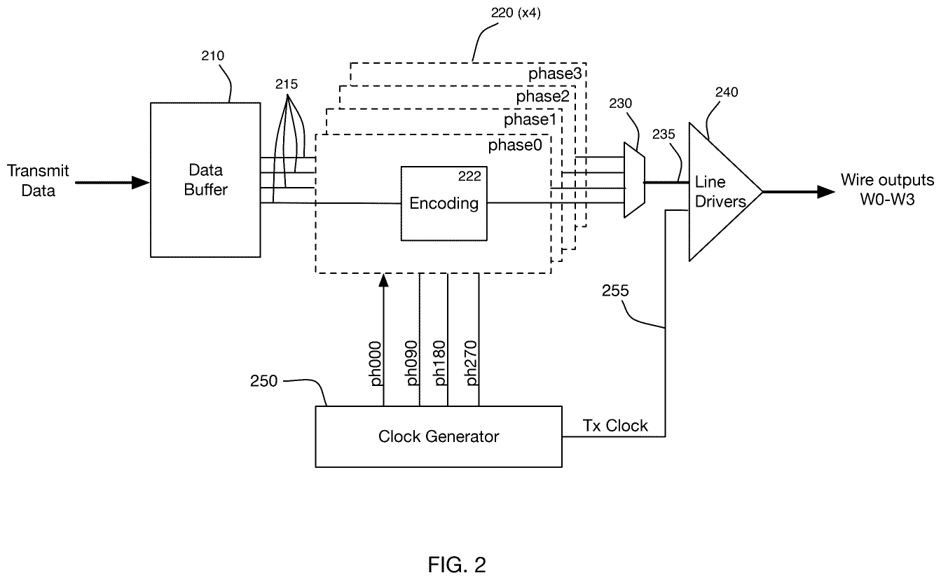

FIG. 2 illustrates a more detailed block diagram of transmitter 110. In a practical embodiment operating at the example speeds, data will typically be provided using a fairly wide-word interface, to allow a slower transfer rate, with Data Buffer 210 providing the necessary temporary storage and data funneling to the ENRZ sub-channels, which typically transports one bit per unit interval per sub-channel. Multiple data processing phases 220 may be utilized, as are typically used in such high-speed systems. Data Buffer 210 thus reformats Transmit Data into appropriate width for each of the processing phases, but may also distribute data among multiple processing phases to enable parallel computation. Data is encoded 220 and output to Wire outputs W0-W3 by Line Drivers 240 under control of Clock Generator 250. If multiple parallel processing phases are used, multiplexers 230 combine the multiple encoded streams into a single high speed result 235.

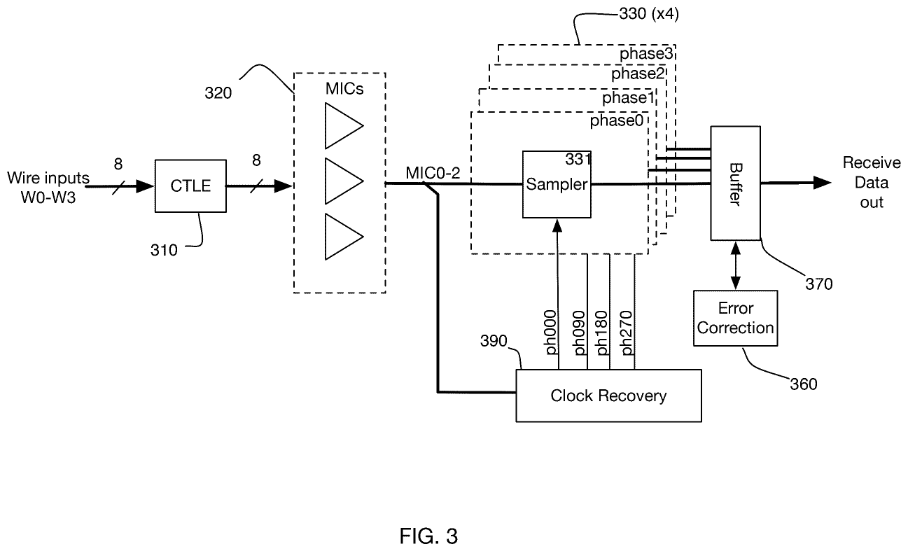

FIG. 3 provides a more detailed block diagram of receiver 130. Signals received over Wire inputs W0-W3 are amplified and frequency compensated by Continuous Time Linear Equalizers (CTLE) 310. ENRZ sub-channels are decoded by Multi-input Comparators (MICs) 320, producing three sub-channel results MIC0-MIC2. Clock Recovery subsystem 390 synthesizes a receive clock from data transitions on received sub-channels MIC0-MIC2. As with the example transmitter, multiple receive processing phases 330 will typically be used to facilitate high speed operation, each such phase sampling the received data using the recovered clock. Buffer 370 allows high speed data received from 330 to be reformatted from the typical one received bit per sub-channel per unit interval, into the wider words and slower transfer rates needed to interface to an external system. In some embodiments such as described in [Shokrollahi III], this buffer also provides temporary storage while Error Correction 360 corrects any detected data errors.

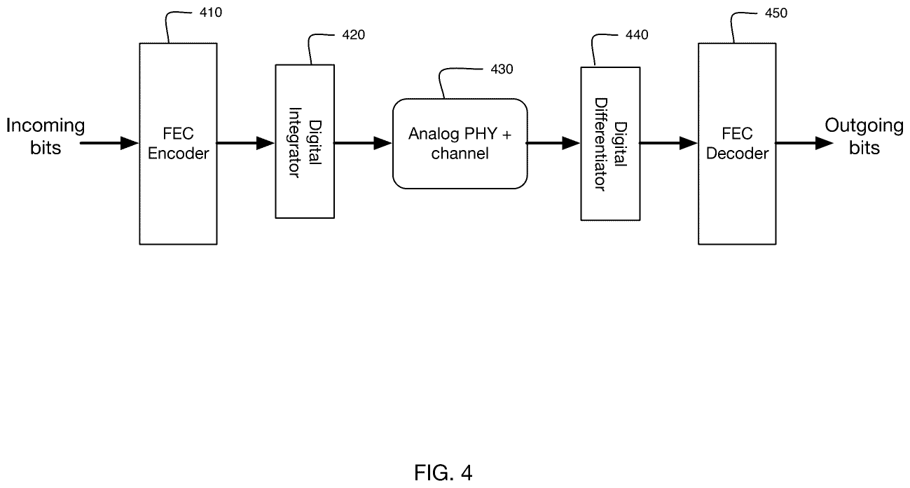

FIG. 4 is a high-level block diagram of the error corrected system, showing the ENRZ transport 430 of FIGS. 1-3 as its lower-level or PHY medium. For descriptive purposes, data is described as passing through this system as streams of bytes, although other embodiments may operate at a different granularity; as previously described, the underlying ENRZ transport typically transmits or receives one bit per sub-channel per unit interval, thus an intrinsic serialization/deserialization is assumed to be part of the PHY embodiment.

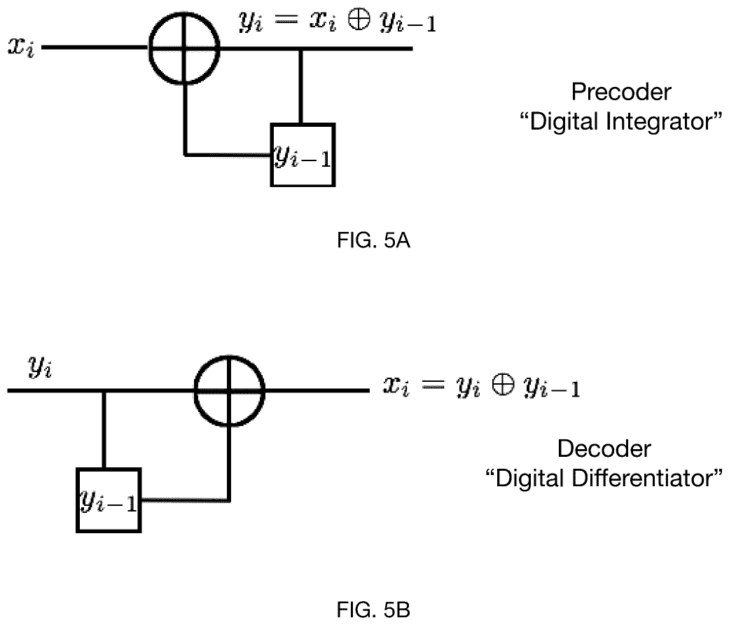

As used herein, the definition of Digital Integrator 420 is as shown as FIG. 5A, and the definition of Digital Differentiator 440 is as shown as FIG. 5B. These functions are used to control the impact of burst errors, with each burst becoming two bit errors after digital differentiation. The descriptive examples presume these functions perform bitwise operations on a data stream, although known art embodiments operating, as one example on streams of bytes are well known thus no limitation is implied.

Without implying limitation, the Forward Error Correcting algorithm assumed in the following descriptions is a Generalized Reed-Solomon code over the Galois Field GF(256), of length 255, capable of 5-error correcting with a 3.92% redundancy. Another embodiment providing 4-error correcting with 3.14% redundancy is functionally equivalent. Both examples are compatible with the interleaving patterns subsequently described.

### Addressing Channel Error Characteristics

Modeling the underlying transport system for error sources, two distinct error modes become apparent. A generalized fault condition or noise source can impact the entire ENRZ transport, introducing codeword errors that lead to essentially simultaneous errors on all sub-channels. Or, more subtly, noise, attenuation, or skew on a subset of the wires may lead to one sub-channel having a substantially higher error rate than the others.

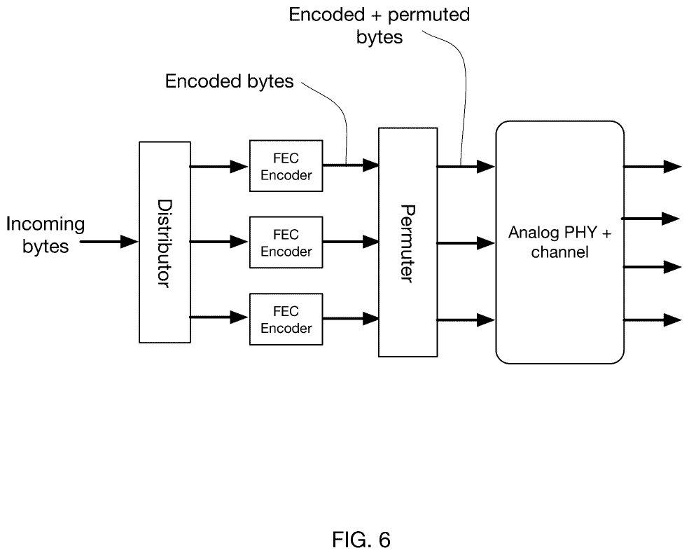

These risks may be mitigated by running separate instances of the FEC algorithm on each of the three ENRZ sub-channels, thus allowing error correction to occur independently. As described in [Fox I], the three sub-channels of the ENRZ code may correspond to mutually orthogonal sub-channel vectors corresponding to rows of an orthogonal matrix. Each row of the orthogonal matrix may be weighted by a respective input bit from e.g., one of the FEC-encoded streams, and all weighted sub-channel vectors may be summed to provide a codeword of the ENRZ vector signaling code. As shown in FIG. 6, a Distributor function distributes or “deals out” incoming data to the individual FEC encoders for transport over the three sub-channels of the ENRZ PHY. In one embodiment, this Distribution is performed on data bytes; other embodiments may perform this distribution at a different granularity. In some embodiments, distributing the streams of FEC-encoded bits as bytes may generate successive sets of codewords, where each successive set of codewords is generated by providing sequential streams of FEC-encoded bits from a given FEC encoder to different sub-channel encoders. Alternatively, if the streams of FEC-encoded bits are distributed of bits, each successive codeword may be generated by providing sequential FEC-encoded bits from a given FEC encoder to different sub-channel encoders.

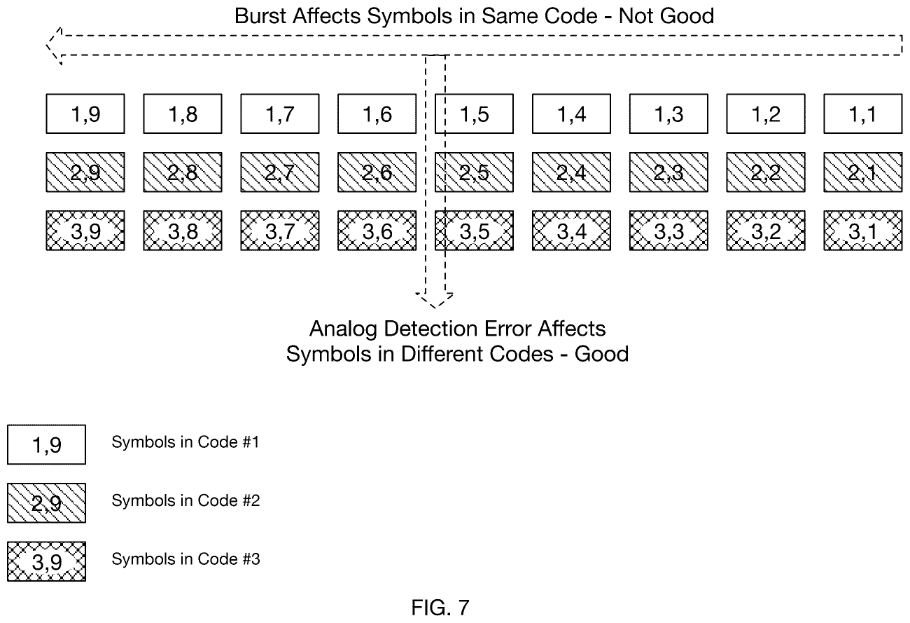

How this “dealing out” is performed has a significant impact on error containment. An obvious sequential ordering (i.e. allowing parallel streams of data to be transmitted on the three sub-channels) is equivalent to an embodiment having a fall-through or “no op” behavior of the Permuter function of FIG. 6. Such a sequence is shown in FIG. 7, where each sub-channel of the ENRZ code carries a respective stream of FEC-encoded data from a respective FEC encoder. Even with this simple sequential byte ordering within each sub-channel, potential errors in PHY analog detection (as may be caused by generalized faults) affects symbols in different sub-channels (e.g. in different FEC streams), which is a recoverable error. However, persistent weaknesses leading to burst errors in a single sub-channel may affect consecutive symbols in the same FEC-encoded stream, potentially overwhelming the sequential error correction ability of that sub-channel's FEC. Moreover, the sequential transmission of the relatively long FEC blocks leads to increased data latency, as the receiver cannot release a given data block until all of its contents have been received and its error detection values validated.

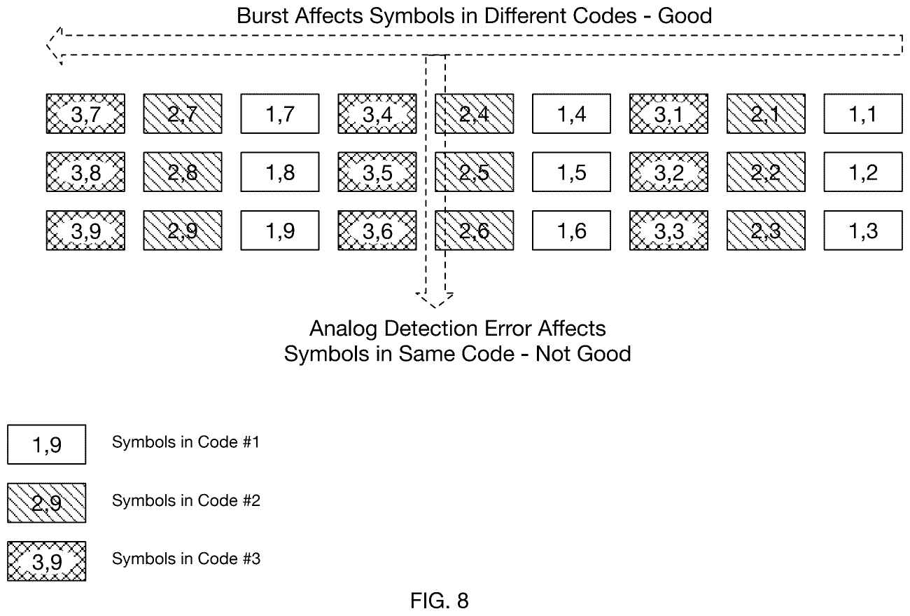

A second embodiment modifies the Permuter function of FIG. 6 to subdivide a given FEC-encoded stream of incoming bytes into groups of three bytes, which are then dealt out consistently in a “1, 2, 3” order to the three ENRZ sub-channels by simultaneously providing all three bytes to respective sub-channel encoders. As shown in FIG. 8, such a consistent interleaving significantly reduces the perceived data latency and provides increased robustness against burst errors in a single sub-channel. However, as consecutive bytes are now transmitted concurrently in the three sub-channels, there may be a potential for errors in analog detection affecting three symbols in the same code, leading to uncorrectable errors.

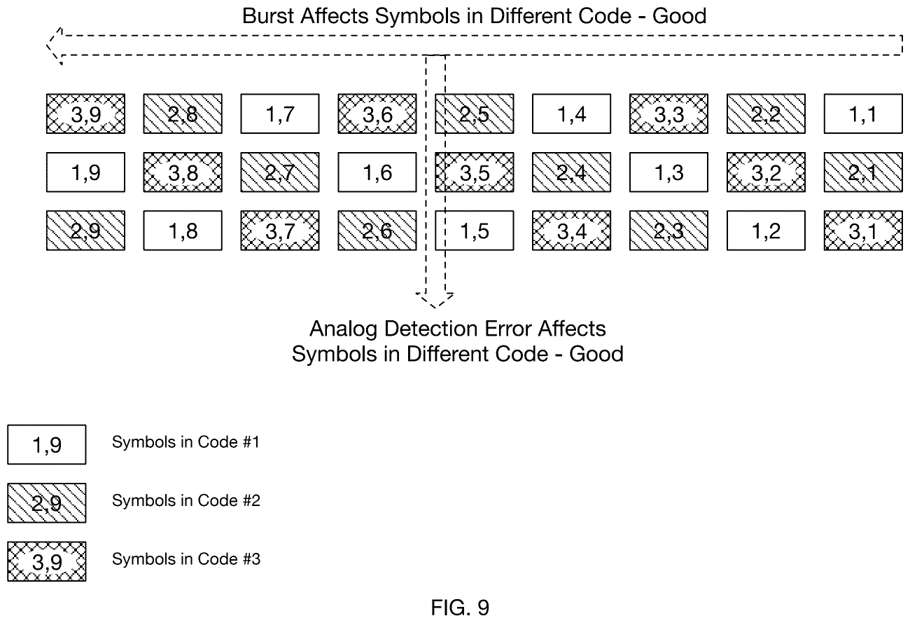

In at least one embodiment, the Permuter function of FIG. 6 cyclically permutes the order in which each group of e.g., three bytes is dealt out. As shown in FIG. 9, which byte of the three bytes is the first to be dealt out differs in each three-byte set of the three FEC-encoded streams. Such a permutation protects against both burst errors within a single sub-channel, and burst errors occurring across all sub-channels, while preserving the desirable latency reduction of the previous embodiment.

### Permuter Embodiments

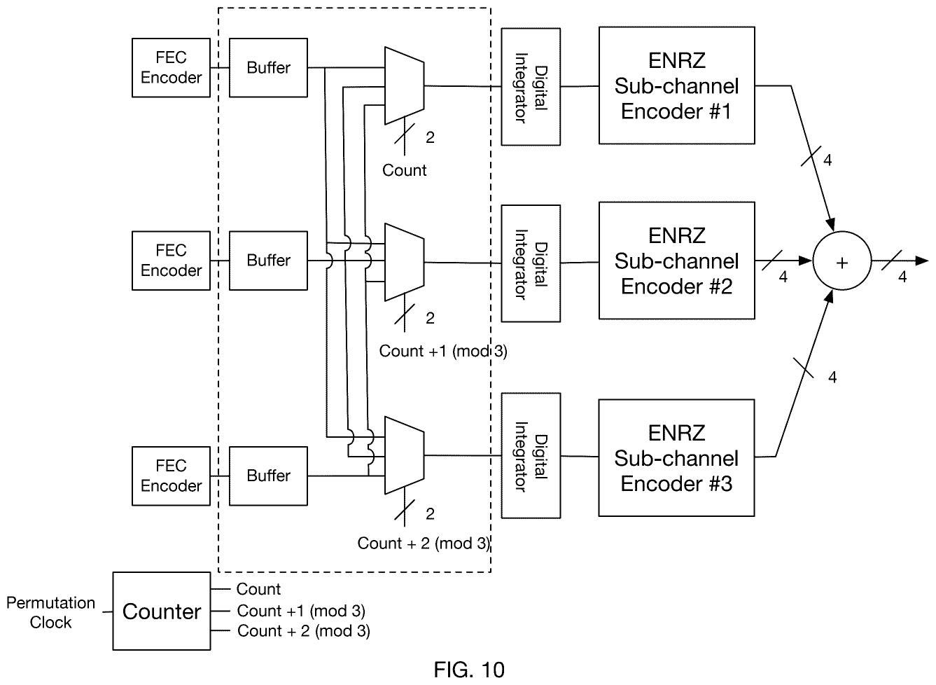

FIG. 10 is a block diagram illustrating one implementation of the permuter shown in FIG. 6. As shown, the permuter includes a plurality of buffers configured to store streams of FEC-encoded bits from a respective FEC encoder of the plurality of FEC encoders. Each buffer may receive the stream of FEC-encoded bits pre-serialized from the FEC encoders, or may alternatively perform a serialization operation on FEC-encoded bits received in parallel. The permuter may further include a plurality of multiplexors configured to receive a stream of FEC-encoded bits from each buffer, and to responsively select which stream of FEC-encoded bits to provide to the corresponding digital integrators. As shown, each multiplexor receives a corresponding selection signal corresponding to staggered versions of a count signal provided by the counter. In the embodiment shown, the counter may be configurable to count 0, 1, 2, 0, 1, 2, and so on according to a (potentially modified) version of the permutation clock. The counter may thus provide three versions of the count signal including count, count+1 (mod 3), and count+2 (mod 3). As shown in FIG. 10, each count signal may be formatted as a pair of bits. Thus, as each multiplexor will receive a count signal being offset by 1 with respect to the other count signals, each sub-channel encoder will receive a bit or a stream of FEC-encoded bits (e.g., a multi-bit packet) from a different buffer when generating a given codeword or set of codewords of the vector signaling code. In some embodiments, the count signal “count” may increment once per byte of transferred data per destination, thus permuting the destination of the FEC encoded stream on byte intervals as illustrated in FIG. 9, while alternative embodiments may effectively increment the counter at a different granularity. The FEC-encoded streams may be provided to sub-channel encoders 1-3 via digital precoding integrators, as shown in FIG. 5A. Each sub-channel encoder may be configured to provide a respective weighted sub-channel vector that is weighted according to the received FEC-encoded stream, all weighted sub-channel vectors being summed to produce the symbols of the codeword to be transmitted via the multi-wire bus.

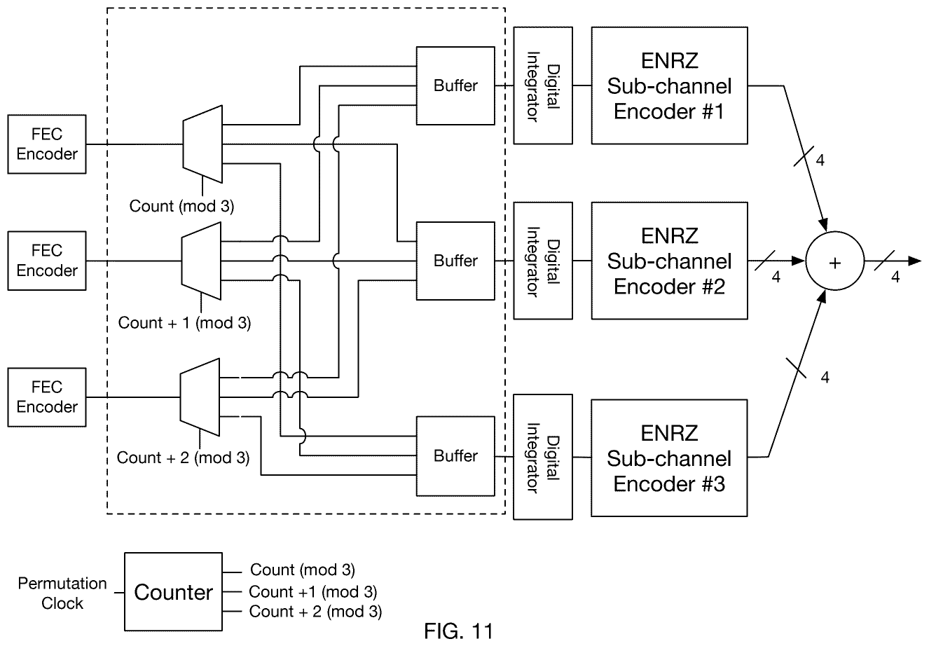

FIG. 11 illustrates an alternative embodiment of a permuter. The permuter of FIG. 11 is similar to that of FIG. 10, however in FIG. 11, each FEC encoder is connected to a corresponding de-multiplexor that selects in which sub-channel specific buffer to store the stream of FEC-encoded bits. Similar to above, the selections may be performed according to staggered count signals in order to permute the destination of the bits provided to each buffer over time. The embodiments of FIGS. 10 and 11 illustrate only two possible embodiments in which the permuter may be implemented, and it should be noted alternative embodiments may be implemented through the use of logic gates in a field-programmable gate array (FPGA), for example, or software running on a processor that uses pointers to either read a stream from a buffer associated with an FEC encoder, or to write a stream from each FEC encoder to a sub-channel specific buffer. Further, a hardware description language may be used to generate a suitable circuit configuration.

Once each sub-channel encoder receives its respective stream (e.g., a byte, a multi-bit packer or in some embodiments a single bit) of FEC-encoded bits, the stream having been serialized for transmission by e.g., the FEC encoder or the buffer, each sub-channel encoder may generate a weighted sub-channel vector by e.g., modulating a corresponding sub-channel vector of a plurality of mutually orthogonal sub-channel vectors. A codeword of a vector signaling code is thus formed representing a weighted summation of the plurality of mutually orthogonal sub-channel vectors, the weight of each sub-channel vector being applied by a corresponding bit in the received serialized stream of FEC-encoded bits. FIGS. 10 and 11 illustrate the output of each sub-channel encoder being summed. In some embodiments, such a summation may be performed as an analog summation in the case each sub-channel encoder outputs an analog signal. Alternatively, each sub-channel encoder may generate and output one or more bits for controlling a multi-level driver to generate symbol values on the multi-wire bus, such as driver 240 in FIG. 2. In some embodiments, the codeword of the vector signaling code may be a permutation of ±[1, −1/3, −1/3, −1/3].

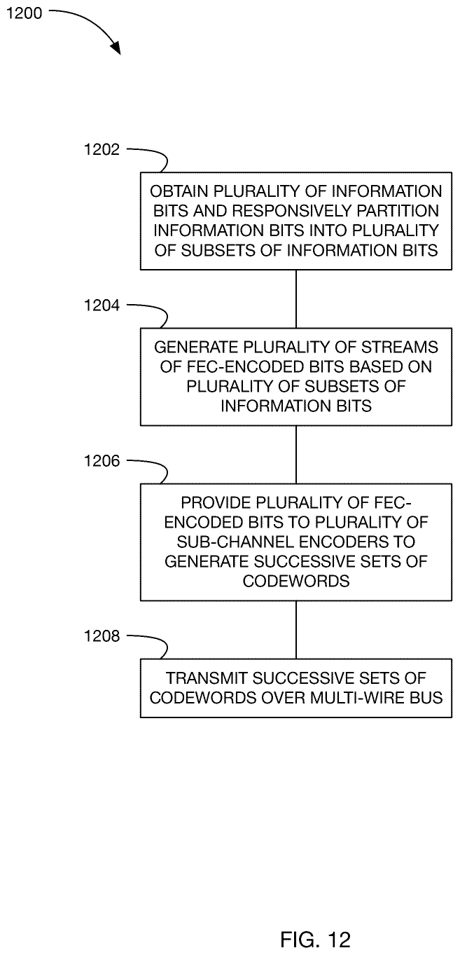

FIG. 12 is a flowchart of a method 1200, in accordance with some embodiments. As shown, method 1200 includes obtaining a plurality of information bits 1202, and responsively partitioning the obtained plurality of information bits into a plurality of subsets of information bits. A plurality of FEC encoders generate 1204 a plurality of streams of forward error correction (FEC)-encoded bits, the plurality of FEC encoders receiving respective subsets of the plurality of subsets of information bits. The plurality of streams of FEC-encoded bits are provided 1206 to a plurality of sub-channel encoders for generating successive sets of codewords of a vector signaling code. Each sub-channel encoder receives a respective stream of FEC-encoded bits from a different FEC encoder of the plurality of FEC encoders for generating a set of codewords of a vector signaling code. Sequential streams of FEC-encoded bits from a given FEC encoder are provided to different sub-channel encoders for each successively generated set of codewords. The successively generated sets of codewords of the vector signaling code are transmitted 1208 over a multi-wire bus.

In some embodiments, each stream of FEC encoded bits corresponds to a multi-bit packet. Alternatively, each stream of FEC encoded bits may correspond to a single bit.

In some embodiments, generating each codeword of the set of codewords of the vector signaling code includes modulating mutually-orthogonal sub-channel vectors on the multi-wire bus according to the plurality of streams of FEC-encoded bits and responsively forming a summation of the modulated mutually-orthogonal sub-channel vectors.

In some embodiments, each stream of FEC encoded bits is provided to the corresponding sub-channel encoder using a corresponding multiplexor of a plurality of multiplexors, each multiplexor receiving all of the streams of FEC encoded bits and associated with a corresponding sub-channel encoder. Alternatively, each stream of FEC-encoded bits is selectively provided to the corresponding sub-channel encoder via a de-multiplexor of a plurality of de-multiplexors, each de-multiplexor associated with a corresponding FEC encoder.

In some embodiments, the plurality of streams of FEC encoded bits are buffered prior to providing the plurality of streams of FEC encoded bits to the plurality of sub-channel encoders.

In some embodiments, the sub-channel encoders are ENRZ sub-channel encoders.

In some embodiments, sequential streams of FEC-encoded bits are provided to corresponding sub-channel encoders according to respective count signals of a plurality of count signals, the plurality of count signals being staggered in time.

In some embodiments, each stream of FEC encoded bits is integrated prior to being provided to the corresponding sub-channel encoder.

Descriptive terms used herein such as “voltage” or “signal level” should be considered to include equivalents in other measurement systems, such as “current”, “charge”, “power”, etc. As used herein, the term “signal” includes any suitable behavior and/or attribute of a physical phenomenon capable of conveying information. The information conveyed by such signals may be tangible and non-transitory.

Note that where various hardware elements of one or more of the described embodiments are referred to as “modules” that carry out (perform, execute, and the like) various functions that are described herein, a module includes hardware (e.g., one or more processors, one or more microprocessors, one or more microcontrollers, one or more microchips, one or more application-specific integrated circuits (ASICs), one or more field programmable gate arrays (FPGAs), one or more memory devices) deemed suitable by those of skill in the relevant art for a given implementation. Each described module may also include instructions executable for carrying out the one or more functions described as being carried out by the respective module, and those instructions may take the form of or include hardware (or hardwired) instructions, firmware instructions, software instructions, and/or the like, and may be stored in any suitable non-transitory computer-readable medium or media, such as commonly referred to as RAM or ROM.

Although features and elements are described above in particular combinations, one of ordinary skill in the art will appreciate that each feature or element may be used alone or in any combination with the other features and elements. In addition, the methods described herein may be implemented in a computer program, software, or firmware incorporated in a computer-readable medium for execution by a computer or processor. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

1-20. (canceled)

21. An apparatus comprising:
a plurality of forward error-correction (FEC) encoders configured to receive an input stream, and to responsively generate a plurality of FEC-encoded blocks of data, each FEC-encoded block of data generated from a respective FEC encoder operating on a respective portion of the input stream;
a permuter circuit configured to receive each FEC-encoded block of data, and to responsively provide first bytes of each FEC-encoded block in an interleaved sequence to a plurality of transport channels for parallel transmission during a first time interval, and wherein over a plurality of subsequent time intervals, the permuter is configured to provide additional bytes of each FEC-encoded block in a cyclically-shifted version of the interleaved sequence to the plurality of transport channels.

22. The apparatus of claim 21, wherein the permuter is configured to select different FEC encoder outputs for each transport channel using multiplexing circuits for the first and second time intervals to provide the first and additional bytes of the FEC-encoded blocks to the plurality of transport channels.

23. The apparatus of claim 21, further comprising a distribution circuit configured to receive the input stream and to distribute the respective portions of the input stream to each FEC encoder.

24. The apparatus of claim 21, wherein each FEC-encoded block comprises respective (i) data symbols containing respective groups of bits from the input stream and (ii) redundancy symbols calculated based on the data symbols.

25. The apparatus of claim 24, wherein the redundancy symbols comprise first and second redundancy symbols associated with respective rows of a check matrix, the check matrix comprising (i) a row of all one elements and (ii) a row of binary expansions of unique integers corresponding to respective symbol indices.

26. The apparatus of claim 21, wherein the plurality of transport channels correspond to a plurality of mutually orthogonal sub-channels of an orthogonal differential vector signaling code.

27. The apparatus of claim 26, wherein the plurality of mutually orthogonal sub-channels of the ODVS code correspond to rows of a Hadamard matrix of size 4.

28. The method of claim 21, wherein the plurality of FEC encoders comprises three FEC encoders.

29. An apparatus comprising:
A plurality of forward error correction (FEC) encoders configured to receive input data for transmission over a plurality of transport channels, the plurality of FEC encoders configured to generate sets of FEC encoded data bytes by encoding respective subsets of the received input data; and
a permuter circuit configured to provide at least one first byte from each of the sets of FEC encoded data bytes in a first interleaved sequence to the plurality of transport channels for transmission in a first transmission time interval, and to provide at least one second byte from each of the sets of FEC encoded data bytes in a second interleaved sequence to the plurality of transport channels for transmission in a second transmission time interval, the second interleaved sequence being a cyclically shifted version of the first interleaved sequence.

30. The apparatus of claim 29, wherein each set of FEC-encoded data bytes comprises respective (i) data bytes containing respective groups of bits from the input stream and (ii) redundancy symbols calculated based on the data bytes.

31. The apparatus of claim 30, wherein the redundancy symbols comprise first and second redundancy symbols associated with respective rows of a check matrix, the check matrix comprising (i) a row of all one elements and (ii) a row of binary expansions of unique integers corresponding to respective symbol indices.

32. The apparatus of claim 29, wherein the plurality of transport channels correspond to a plurality of mutually orthogonal sub-channels of an orthogonal differential vector signaling (ODVS) code.

33. The apparatus of claim 32, wherein the plurality of mutually orthogonal sub-channels of the ODVS code correspond to rows of a Hadamard matrix of size 4.

34. The apparatus of claim 33, further comprising a plurality of ODVS encoders, each ODVS encoder configured to receive respective FEC-encoded data bytes from the permute and to generate symbols of a stream of ODVS codewords.

35. The apparatus of claim 29, further comprising a distribution circuit configured to receive the input data, and to distribute the respective subsets of the received input data to the plurality of FEC encoders.

36. An apparatus comprising:
a distribution circuit configured to receive an input stream, and to distribute subsets of the input stream to respective forward error correction (FEC) encoders of a plurality of FEC encoders;
the plurality of FEC encoders configured to generate a plurality of FEC-encoded blocks of data, each FEC-encoded block of data generated from the respective subset of the input stream; and
a permuter circuit configured to allocate bytes of each of the plurality of FEC-encoded blocks of data in an interleaved sequence in parallel to a plurality of transport channels for parallel transmission over a sequence of time intervals, wherein the FEC encoder selected by the permuter circuit to provide bytes to a given transport channel varies with each time interval, and wherein the permuter circuit is configured to interleave bytes provided by all of the FEC encoders across the plurality of transport channels in a given time interval.

37. The apparatus of claim 36, wherein each set of FEC-encoded data bytes comprises respective (i) data bytes containing respective groups of bits from the input stream and (ii) redundancy symbols calculated based on the data bytes.

38. The apparatus of claim 37, wherein the redundancy symbols comprise first and second redundancy symbols associated with respective rows of a check matrix, the check matrix comprising (i) a row of all one elements and (ii) a row of binary expansions of unique integers corresponding to respective symbol indices.

39. The apparatus of claim 36, wherein the plurality of FEC encoders comprises three FEC encoders.

40. The method of claim 36, wherein the plurality of transport channels correspond to sub-channels of an orthogonal differential vector signaling code.
